(19) United States
(12) Patent Application Publication
(10) Pub. No.: US 2026/0011653 A1
(43) Pub. Date: Jan. 8, 2026

(54) SEMICONDUCTOR PACKAGE

(71) Applicant: Samsung Electronics Co., Ltd., Suwon-si (KR)

(72) Inventors: Jeonggi Jin, Suwon-si (KR); Unbyoung Kang, Suwon-si (KR); Jiyoung Park, Suwon-si (KR); Hyunah Kim, Suwon-si (KR)

(21) Appl. No.: 18/983,837

(22) Filed: Dec. 17, 2024

(30) Foreign Application Priority Data
Jul. 5, 2024 (KR) 10-2024-0089049

(51) Int. Cl. H01L 23/538; H01L 21/683; H01L 21/78; H01L 23/00; H01L 23/29; H01L 23/31; H01L 23/367; H01L 23/498; H01L 25/065

(52) U.S. Cl. CPC H01L 23/5389; H01L 23/29; H01L 23/3128; H01L 23/49833; H01L 23/49838; H01L 23/49866; H01L 23/5385; H01L 23/5386; H01L 25/0655; H01L 21/683; H01L 21/78; H01L 23/3672; H01L 23/5381; H01L 24/06; H01L 24/16; H01L 2224/06131; H01L 2224/16227

(57) ABSTRACT

A semiconductor package includes a redistribution structure including redistribution patterns, first and second chip structures on the redistribution structure and electrically connected to the redistribution patterns, a first mold covering at least a portion of each of the first and second chip structures, an interconnection chip including interconnection patterns electrically connected to the redistribution patterns and a plurality of insulating layers having third surfaces in which respective ones of the interconnection patterns are embedded, through-vias electrically connected to the redistribution patterns, a second mold covering at least a portion of each of the through-vias and the interconnection chip. Each third surface includes a first region, and a second region between the first region and an upper surface of the respective interconnection pattern embedded in the third surface. The second region defines a step between the first region and the upper surface of the interconnection pattern embedded in the third surface.

### CROSS-REFERENCE TO RELATED APPLICATION(S)

This application claims the benefit under 35 USC 119 (a) of Korean Patent Application No. 10-2024-0089049 filed on Jul. 5, 2024, in the Korean Intellectual Property Office, the entire disclosure of which is incorporated herein by reference for all purposes.

### FIELD

The present inventive concept relates to a semiconductor package.

### BACKGROUND

Semiconductor devices installed in electronic devices require miniaturization as well as high performance and large capacity. To this end, system-in-package (SiP) technology is being developed to interconnect heterogeneous semiconductor chips within a single semiconductor package.

### SUMMARY

Example embodiments provide a semiconductor package having improved productivity and reliability.

According to example embodiments, a semiconductor package includes a redistribution structure having a first surface and a second surface opposing each other, and including redistribution patterns; a first chip structure and a second chip structure disposed on the first surface of the redistribution structure and electrically connected to the redistribution patterns; a first mold covering at least a portion of each of the first and second chip structures; an interconnection chip disposed on the second surface of the redistribution structure, and including interconnection patterns electrically connected to the redistribution patterns and a plurality of insulating layers each having a third surface, wherein each of the third surfaces includes a respective one of the interconnection patterns embedded therein; through-vias disposed around the interconnection chip and electrically connected to the redistribution patterns; a second mold covering at least a portion of each of the through-vias and the interconnection chip; and bump structures disposed below the second mold and electrically connected to the through-vias. Each third surface includes a first region, and a second region between the first region and an upper surface of the respective interconnection pattern embedded in the third surface. The second region defines a step between the first region and the upper surface of the respective interconnection pattern embedded in the third surface.

According to example embodiments, a semiconductor package includes a first redistribution structure having a first surface and a second surface opposing each other, and including first redistribution patterns; a first chip structure and a second chip structure disposed on the first surface of the first redistribution structure and electrically connected to the first redistribution patterns; a first mold covering at least a portion of each of the first and second chip structures; an interconnection chip disposed on the second surface of the first redistribution structure, and including a chip body, interconnection patterns embedded within the chip body and electrically connected to the first redistribution patterns, and a metal layer disposed below the chip body; through-vias disposed around the interconnection chip and electrically connected to the first redistribution patterns; a second mold covering the interconnection chip and at least portions of the through-vias; and bump structures disposed below the second mold and electrically connected to the through-vias. The chip body includes a flexible material, and the metal layer is electrically insulated from the interconnection patterns.

According to example embodiments, a semiconductor package includes a redistribution structure having a first surface and a second surface opposing each other, and including redistribution patterns; a first chip structure and a second chip structure disposed on the first surface of the redistribution structure and electrically connected to the redistribution patterns; a first mold covering at least a portion of each of the first and second chip structures; an interconnection chip disposed on the second surface of the redistribution structure, and including a chip body, interconnection patterns embedded in the chip body and electrically connected to the redistribution patterns, and a plurality of passivation layers disposed between the chip body and the redistribution patterns; through-vias disposed around the interconnection chip and electrically connected to the redistribution patterns; a second mold covering a side surface and a lower surface of the interconnection chip and respective side surfaces of the through-vias; and bump structures disposed below the second mold and electrically connected to the through-vias. The chip body contains an organic compound, and the plurality of passivation layers contain an inorganic compound.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view of a semiconductor package according to some embodiments.

FIG. 1B is a cross-sectional view taken along line I-I′ of FIG. 1A;

FIG. 1C is a partial enlarged view of area ‘A’ of FIG. 1B;

FIG. 1D is a partial enlarged view of area ‘B’ in FIG. 1C;

FIG. 2A is a partially enlarged view of a semiconductor package according to further embodiments;

FIG. 2B is a partially enlarged view of area ‘C’ of FIG. 2A;

FIG. 3A is a cross-sectional view of a semiconductor package according to further embodiments;

FIG. 3B is a partially enlarged view of area ‘D’ of FIG. 3A;

FIG. 4 is a cross-sectional view of a semiconductor package according to further embodiments;

FIG. 5 is a cross-sectional view of a semiconductor package according to further embodiments;

FIG. 6 is a cross-sectional view of a semiconductor package according to further embodiments;

FIG. 7 is a cross-sectional view of a semiconductor package according to further embodiments;

FIG. 8 is a cross-sectional view of a semiconductor package according to further embodiments;

FIGS. 9A to 9F are diagrams illustrating a process of manufacturing an interconnection chip according to some embodiments; and

FIGS. 10A to 10E are diagrams illustrating a process of manufacturing a semiconductor package according to some embodiments.

### DETAILED DESCRIPTION

The above and other aspects and features of the semiconductor package and the methods of manufacturing the same in accordance with example embodiments will become readily understood from the detailed descriptions that follow, with reference to the accompanying drawings.

In the drawings, the thickness of layers, films, panels, regions, etc., are exaggerated for clarity, and like reference numerals designate like elements throughout the specification.

Unless otherwise specified, in this specification, terms such as ‘upper’, ‘upper surface’, ‘lower’, ‘lower surface’, ‘side’ and the like are based on the drawings, and actually, may vary depending on the direction in which the components are disposed.

Additionally, ordinal numbers such as “first,” “second,” “third,” etc. may be used as labels for specific elements, steps, directions, etc. to distinguish various elements, steps, directions, etc. from each other. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process. Terms that are not described using “first,” “second,” etc. in the specification may still be referred to as “first” or “second” in the claims. Additionally, terms (for example, “first” in a particular claim) referenced by a particular ordinal number may be described elsewhere with a different ordinal number (for example, “second” in the specification or another claim). The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

Components or layers described with reference to “overlap” in a particular direction are at least partially obstructed by one another when viewed along a line extending in the particular direction or in a plane perpendicular to the particular direction. As used herein, “an element A overlapping an element B in a direction C” (or similar language) means that there is at least one line that extends in the direction C that intersects both the element A and the element B. For example, the element B may be a layer that is stacked or superimposed over (i.e., on top of) the element A, in which case the layer B may be described as overlapping the element A in a vertical direction. However, it will be appreciated that the direction C is not limited to the vertical direction and may be, for example, a horizontal direction or any direction between vertical and horizontal.

The term “exposed” may be used to describe relationships between elements and/or certain intermediate processes in fabricating a completed semiconductor device but may not necessarily require exposure of the particular region, layer, structure or other element in the context of the completed device. An “element A is exposed by an element B” means that at least a portion of the element A is not covered by the element B. However, the thus exposed portion of the element A may be covered by a third element.

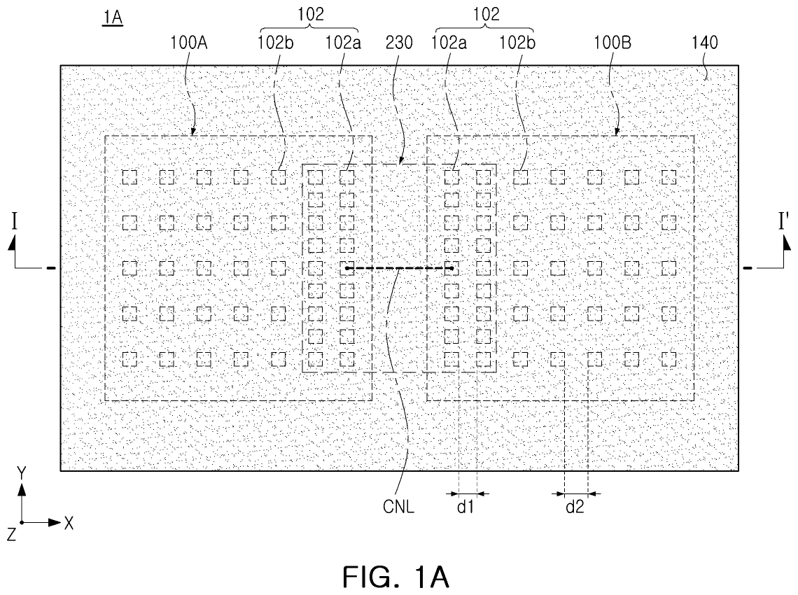

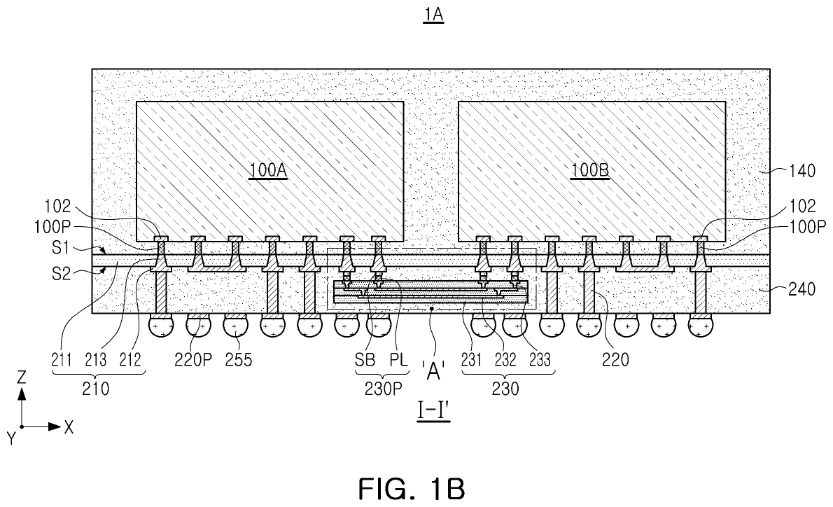

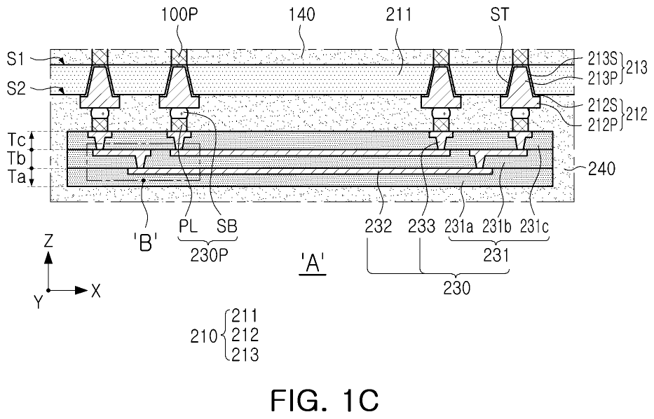

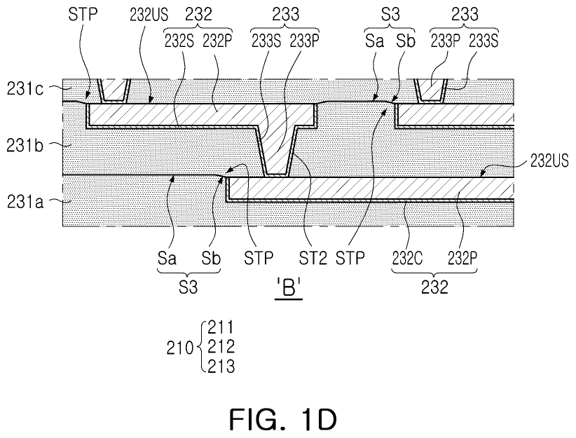

FIG. 1A is a plan view of a semiconductor package 1A according to an example embodiment, FIG. 1B is a cross-sectional view taken along line I-I′ of FIG. 1A, FIG. 1C is a partially enlarged view of the ‘A’ region of FIG. 1B, and FIG. 1D is a partial enlarged view of area ‘B’ in FIG. 1C.

Referring to FIGS. 1A to 1D, a semiconductor package 1A of an example embodiment may include a plurality of chip structures 100A and 100B, a redistribution structure 210, through-vias 220, and an interconnection chip 230. Additionally, the semiconductor package 1A may further include a first mold 140, a second mold 240, and/or bump structures 255.

A plurality of chip structures 100A and 100B may be arranged side surface by side surface on the first surface S1 of the redistribution structure 210. The plurality of chip structures 100A and 100B may be arranged to be spaced apart from each other in the horizontal direction (X-direction or Y-direction). The plurality of chip structures 100A and 100B may at least partially overlap the interconnection chip 230 in the vertical direction (Z-direction). For example, the plurality of chip structures 100A and 100B may include a first chip structure 100A and a second chip structure 100B, respectively, overlapping at least a portion of the interconnection chip 230.

The plurality of chip structures 100A and 100B may be electrically connected to each other through connection lines CNL of the interconnection chip 230. In this case, ‘connection lines (CNL)’ may be understood as electrically conductive lines in which interconnection patterns 232 and interconnection vias 233, which will be described later, are combined. The plurality of chip structures 100A and 100B may be electrically connected to the bump structures 255 through through-vias 220. Each of the plurality of chip structures 100A and 100B may include a plurality of pads 102. The plurality of pads 102 may include first pads 102a connected to the interconnection chip 230 and second pads 102b connected to the bump structures 255. The first pads 102a may be arranged at a finer pitch than the second pads 102b. For example, the first gap d1 (FIG. 1A) between adjacent first pads 102a may be smaller than the second gap d2 between adjacent second pads 102b, but is not limited thereto. Depending on some example embodiments, the plurality of pads 102 may be electrically connected to the redistribution patterns 212 through the connection bump 100P.

The first chip structure 100A and the second chip structure 100B may include logic chips (or processor chips) such as a central processor (CPU), a graphics processor (GPU), a field programmable gate array (FPGA), an application processor (AP), a digital signal processor, a cryptographic processor, a microprocessor, a microcontroller, an analog-to-digital converter, an application-specific IC (ASIC), an application processor (AP), and the like, and memory chips including a volatile memory such as a dynamic RAM (DRAM) and a static RAM (SRAM), and a non-volatile memory such as a phase change RAM (PRAM), a magnetic RAM (MRAM), a resistive RAM (RRAM), and a flash memory.

Depending on some example embodiments, the first chip structure 100A and the second chip structure 100B may include different types of semiconductor chips. For example, the first chip structure 100A may include a logic chip such as a CPU, GPU, or ASIC, and the second chip structure 100B may include a memory chip such as a DRAM or flash memory.

The redistribution structure 210 (or referred to as ‘first redistribution structure’) has a first surface S1 and a second surface S2 opposing each other, and may include a dielectric layer 211, redistribution patterns 212, and redistribution vias 213. Hereinafter, the dielectric layer 211, redistribution patterns 212, and redistribution vias 213 may be referred to as first dielectric layer 211, first redistribution patterns 212, and first redistribution vias 213, respectively.

The dielectric layer 211 may be formed using a photosensitive polymer. For example, the dielectric layer 211 may include polyimide (PI)-based photosensitive polymer, polybenzoxazole (PBO)-based photosensitive polymer, polyhydroxystyrene (PHS)-based photosensitive polymer, novolak-based photosensitive polymer, benzocyclobutene (BCB)-based photosensitive polymer, or Photo Imageable Dielectric (PID). The dielectric layer 211 may be formed of a larger number of layers (for example, 2 layers, 3 layers, or the like) than that (1 layer) illustrated in the drawing. Depending on the process, the boundaries of respective layers may be unclear.

The redistribution patterns 212 are disposed on or within the dielectric layer 211 and may be electrically connected to the interconnection chip 230, the through-vias 220, and the plurality of chip structures 100A and 100B. The redistribution patterns 212 may include, for example, copper (Cu), aluminum (Al), silver (Ag), tin (Sn), gold (Au), nickel (Ni), lead (Pb), titanium (Ti), or alloys thereof. The redistribution patterns 212 may include an electrically conductive layer 212P containing copper (Cu) and a seed layer 212S containing titanium (Ti), copper (Cu), or the like. The seed layer 212S may be disposed between the conductive layer 212P and the dielectric layer 211. The redistribution patterns 212 may include a ground pattern, a power pattern, and a signal pattern depending on the design. The signal pattern may provide a transmission path for various signals (for example, data signals) excluding ground patterns, power patterns, and the like. The redistribution patterns 212 may include various types of conductive lines extending in the horizontal direction (X and/or Y). The redistribution patterns 212 may substantially redistribute the pads 102 of the plurality of chip structures 100A and 100B.

The redistribution vias 213 may penetrate the dielectric layer 211 and be electrically connected to the redistribution patterns 212. In an example embodiment, the redistribution vias 213 may electrically connect the redistribution patterns 212 disposed on the second surface S2 to the first and second chip structures 100A and 100B. The redistribution vias 213 may have a side surface ST tapered toward the first surface S1 (i.e., the side surface ST tapers inwardly in a direction from the surface S2 to the surface S1). The redistribution vias 213 may include, for example, copper (Cu), aluminum (Al), silver (Ag), tin (Sn), gold (Au), nickel (Ni), lead (Pb), titanium (Ti), or alloys thereof. The redistribution vias 213 may include an electrically conductive layer 213P containing copper (Cu), and a seed layer 213S containing titanium (Ti), copper (Cu), or the like. The conductive layer 213P and the seed layer 213S of the redistribution vias 213 may be formed integrally with the conductive layer 212P and the seed layer 212S of the redistribution patterns 212, but the present inventive concept is not limited thereto. The redistribution vias 213 may be filled vias in which the inside of the via hole is filled with a metal material, or conformal vias in which a metal material is formed along the inner wall of the via hole.

The through-vias 220 are disposed around the interconnection chip 230 and may be electrically connected to the redistribution patterns 212. The through-vias 220 may have a post shape extending in the vertical direction (Z) corresponding to the thickness of the interconnection chip 230. One surface (for example, lower surface) of the through-vias 220 may be coplanar with one surface (for example, lower surface) of the second mold 240 through a planarization process. The through-vias 220 may include copper (Cu), aluminum (Al), silver (Ag), tin (Sn), gold (Au), nickel (Ni), lead (Pb), titanium (Ti), or alloys thereof. A seed layer may be formed between the through-vias 220 and the redistribution patterns 212 or pad portions of the redistribution patterns 212.

The interconnection chip 230 may be disposed on the second surface S2 of the redistribution structure 210 and may include a chip body 231, interconnection patterns 232, and interconnection vias 233. The interconnection chip 230 may have a size or a horizontal area that may respectively overlap the plurality of chip structures 100A and 100B in the vertical direction (Z-direction).

The chip body 231 may include a flexible material, for example, a flexible polymer material. Accordingly, the risk of cracks occurring in the chip body 231 may be reduced and productivity may be improved. The chip body 231 may include a plurality of insulating layers 231a, 231b, and 231c formed using PID. The plurality of insulating layers 231a, 231b, and 231c may include, for example, a PI-based photosensitive polymer, a PBO-based photosensitive polymer, a PHS-based photosensitive polymer, a novolak-based photosensitive polymer, or a BCB-based photosensitive polymer.

According to example embodiments and with reference to FIG. 1D, the interconnection patterns 232 are finer than the redistribution patterns 212 using a photolithography process, a dry etching process, or the like, and may be embedded in surfaces of the corresponding plurality of insulating layers 231a, 231b, and 231c. Each of the plurality of insulating layers 231a, 231b, and 231c may have a third surface S3 (FIG. 1D) in which interconnection patterns 232 are embedded. The third surfaces S3 of the plurality of insulating layers 231a, 231b, and 231c may each include a first region Sa having, defining or forming a step STP with the upper surface 232US of the respective one of the interconnection patterns 232 embedded therein, and a second region Sb between the first region Sa and the respective interconnection pattern 232. That is, each third surface S3 includes a first region Sa, and a second region Sb between its first region Sa and the upper surface 232US of the interconnection pattern 232 embedded in said third surface S3, and the second region Sb of said third surface S3 defines a step STP between its first region Sa and the upper surface 232US of the interconnection pattern 232 embedded in said third surface S3. The first region Sa is a flattened surface at a higher level than the upper surface 232US of the corresponding interconnection patterns 232. In some embodiments, the step STP reduces or transitions the height of the third surface S3 from the level or height of the first region Sa to the lower level or height of the corresponding upper surface 232US. Each second region Sb may be a curved surface extending from one end of the first region Sa to one end of the interconnection pattern 232 (e.g., the end of the interconnection pattern 232 adjacent the second region Sb).

With reference to FIG. 1C, the plurality of insulating layers 231a, 231b, and 231c may have substantially the same thickness. For example, the plurality of insulating layers 231a, 231b, and 231c may include a first insulating layer 231a, a second insulating layer 231b, and a third insulating layer 231c that are sequentially stacked. The first thickness Ta of the first insulating layer 231a, the second thickness Tb of the second insulating layer 231b, and the third thickness Tc of the third insulating layer 231c are about 3 μm or more, and for example, may range from about 3 μm to about 8 μm, from about 3 μm to about 7 μm, from about 3 μm to about 6 μm, from about 3 μm to about 5 μm, or the like. In this case, ‘substantially the same’ may be understood to include process errors.

The interconnection patterns 232 are electrically connected to the redistribution patterns 212 and may form an interconnection path between the plurality of chip structures 100A and 100B. The interconnection patterns 232 are formed at a finer pitch than the redistribution patterns 212 and may be embedded in the upper surfaces of the corresponding plurality of insulating layers 231a, 231b, and 231c. The interconnection patterns 232 may include an electrically conductive layer 232P and a seed layer 232S covering the side surface and lower surface of the conductive layer 232P. The conductive layer 232P may include any one of copper (Cu), nickel (Ni), titanium (Ti), aluminum (Al), gold (Au), and silver (Ag), or alloys thereof. The seed layer 232S may include titanium (Ti), tantalum (Ta), or alloys thereof. The interconnection patterns 232 may include various types of conductive lines extending in the horizontal direction (X and/or Y).

The interconnection vias 233 may penetrate the plurality of insulating layers 231a, 231b, and 231c and be electrically connected to the interconnection patterns 232. Each interconnection via 233 may extend from the lower surface of the respective one of the interconnection patterns 232 to the upper surface 232US of an interconnection pattern 232 underlying the respective interconnection pattern 232. Each interconnection via 233 may have a side surface ST2 that tapers toward the upper surface 232US of the corresponding underlying interconnection pattern 232 contacted by the interconnection via 233. The interconnect vias 233 may include a metal material containing, for example, copper (Cu), aluminum (Al), silver (Ag), tin (Sn), gold (Au), nickel (Ni), lead (Pb), titanium (Ti), or alloys thereof. The interconnection vias 233 may include an electrically conductive layer 233P and a seed layer 233S covering the side surface and lower surface of the conductive layer 233P. The conductive layer 232P and the seed layer 232S of the interconnection patterns 232 may be formed integrally with the conductive layer 233P and the seed layer 233S of the interconnection vias 233, but the present inventive concepts are not limited thereto.

The interconnection chip 230 may be electrically connected to the redistribution patterns 212 through interconnection bumps 230P. The interconnection bumps 230P may include a pillar portion PL in contact with the interconnection patterns 232 or a pad portion thereof, and a solder portion SB (FIG. 1B) on the pillar portion PL. The pillar portion (PL) may include copper (Cu) or an alloy of copper (Cu), and the solder portion SB may include a low melting point metal, such as tin (Sn) or an alloy containing tin (Sn). Depending on some example embodiments, the interconnection bumps 230P may include only one of the pillar portion PL and the solder portion SB. In some embodiments, an underfill layer surrounding the interconnection bumps 230P may be disposed between the interconnection chip 230 and the redistribution structure 210. The underfill layer may have a capillary underfill (CUF) structure, but is not limited thereto. The underfill layer may have a molded underfill (MUF) structure integrated with the second mold 240.

In some embodiments, the semiconductor package 1A may further include a first mold 140 for sealing the plurality of chip structures 100A and 100B and a second mold 240 for sealing the interconnection chip 230. The first mold 140 may cover at least a portion of each of the first chip structure 100A and the second chip structure 100B. The second mold 240 may cover at least a portion of each of the interconnection chip 230 and the through-vias 220. The second mold 240 may be in direct contact with the lower surface of the chip body 231 or the lowermost insulating layer (for example, 231a) among the plurality of insulating layers. The first mold 140 and the second mold 240 may include non-photosensitive polymers, such as thermosetting resins such as epoxy resins, thermoplastic resins such as polyimide, or inorganic fillers impregnated with these resins, for example, prepreg, ABF (Ajinomoto Build-up Film), FR-4 (Flame Resistant), BT (Bismaleimide Triazine), Epoxy Molding Compound (EMC) or the like.

The bump structures 255 may be disposed below the second mold 240 and electrically connected to the through-vias 220. Bump structures 255 may be formed on bump pads 220P that contact one end of the through-vias 220. The bump structures 255 may be a solder bump formed of, for example, tin (Sn), indium (In), bismuth (Bi), antimony Sb, copper (Cu), silver (Ag), zinc (Zn), lead (Pb) or alloys thereof (for example, Sn—Ag—Cu). Depending on some example embodiments, the bump structures 255 may have a combination of a pillar portion and a solder portion.

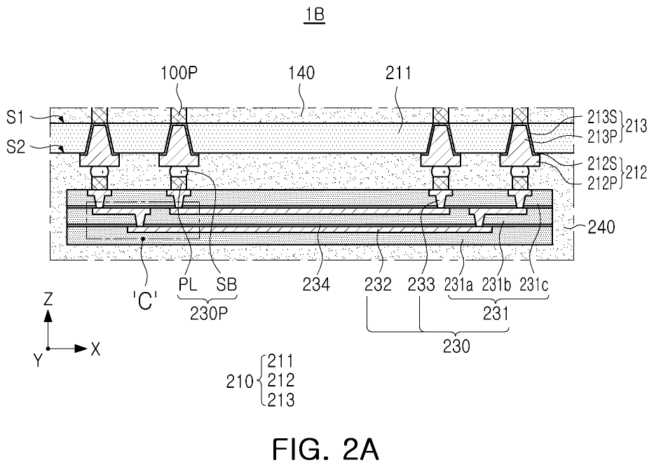

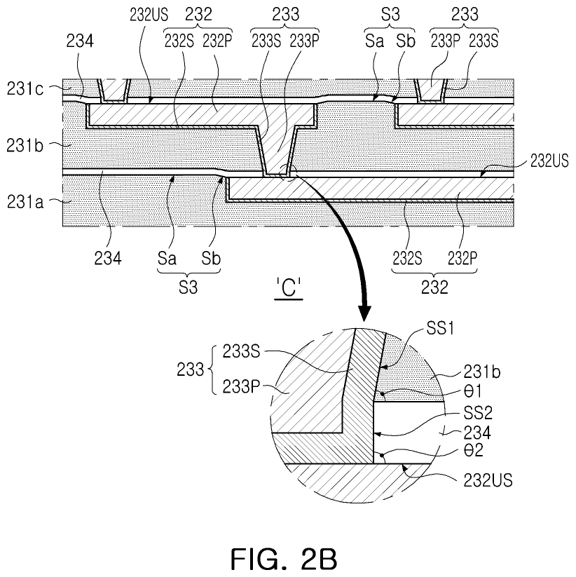

FIG. 2A is a partially enlarged view of a semiconductor package 1B according to further embodiments, and FIG. 2B is a partially enlarged view of the ‘C’ region of FIG. 2A.

Reference numerals used herein and labeled in FIGS. 1A-ID to describe the semiconductor package 1A are also used herein and labeled in FIGS. 2A and 2B to designate similar or corresponding components and features of the semiconductor package 1B.

Referring to FIGS. 2A and 2B, the semiconductor package 1B of the example embodiment may have the same or similar features as those described with reference to FIGS. 1A to 1D, except that the interconnection chip 230 includes a plurality of passivation layers 234. The interconnection chip 230 may further include a plurality of passivation layers 234 extending between the plurality of insulating layers 231a, 231b, and 231c. A plurality of passivation layers 234 may be disposed between the upper surfaces 232US of the interconnection patterns 232 and the plurality of insulating layers 231a, 231b, and 231c.

The plurality of passivation layers 234 blocks material interaction (for example, metal diffusion) between the interconnection patterns 232 and the plurality of insulating layers 231a, 231b, and 231c, thereby improving reliability of the interconnection chip 230. The plurality of passivation layers 234 may include a material different from the plurality of insulating layers 231a, 231b, and 231c. The chip body 231 or the plurality of insulating layers 231a, 231b, and 231c may contain an organic compound, and the plurality of passivation layers 234 may contain an inorganic compound. For example, the chip body 231 may include a photosensitive polymer, and the plurality of passivation layers 234 may include at least one of silicon oxide (SiO), silicon nitride (SiN), and silicon oxynitride (SiON).

With reference to FIG. 2B, the interconnection vias 233 may include a first side surface SS1 passing through a plurality of corresponding insulating layers 231a, 231b and 231c, and a second side surface SS2 passing through a plurality of passivation layers 234. The first side surface SS1 of each of the interconnection vias 233 has a first inclination angle θ1 with respect to the upper surface 232US of the corresponding interconnection patterns 232, and the second side surface SS2 of each of the interconnection vias 233 may have a second inclination angle θ2 greater than the first inclination angle θ1 with respect to the upper surface 232US of the corresponding interconnection patterns 232. For example, the second inclination angle θ2 may be about 90°, and the first inclination angle θ1 may be less than about 90°.

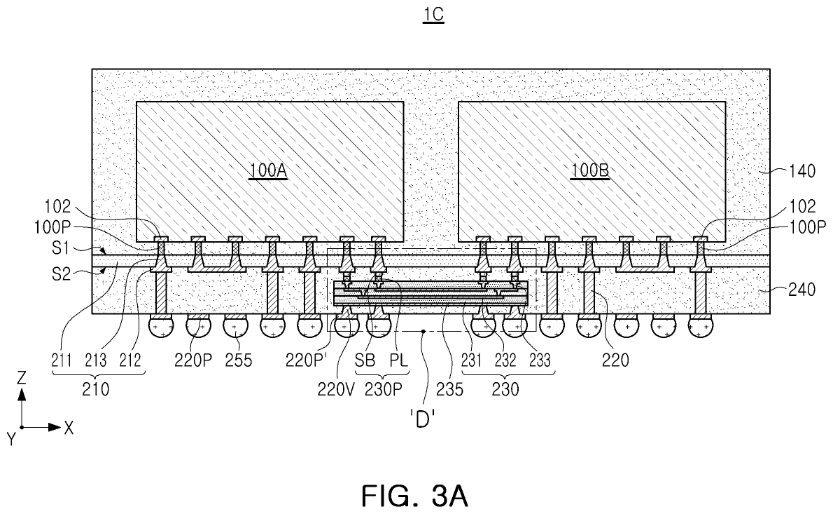

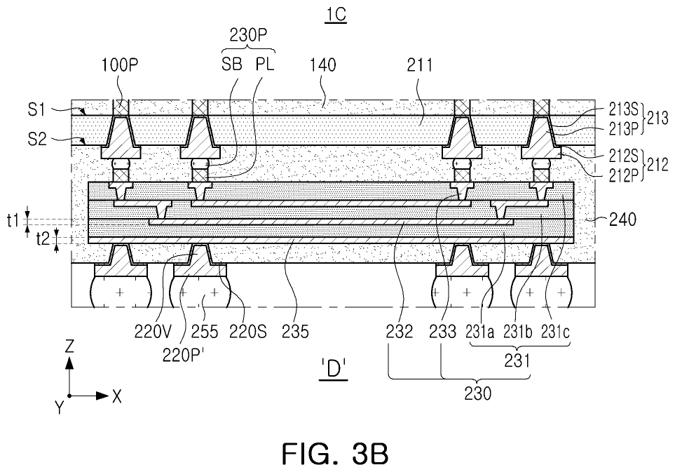

FIG. 3A is a cross-sectional view of the semiconductor package 1C according to further embodiments, and FIG. 3B is a partial enlarged view of the ‘D’ area of FIG. 3A.

Reference numerals used herein and labeled in FIGS. 1A-2B are also used herein and labeled in FIGS. 3A and 3B to designate similar or corresponding components and features of the semiconductor package 1C.

Referring to FIGS. 3A and 3B, the semiconductor package IC of the example embodiment may have the same or similar features as those described with reference to FIGS. 1A to 2B, except that it further includes a metal layer 235 disposed under the interconnection chip 230. The interconnection chip 230 may further include a metal layer 235 disposed below the chip body 231. The metal layer 235 may include, for example, copper (Cu), aluminum (Al), silver (Ag), tin (Sn), gold (Au), nickel (Ni), lead (Pb), titanium (Ti), or alloys thereof. The metal layer 235 may be electrically insulated from the interconnection patterns 232. The metal layer 235 and the lowermost interconnection patterns 232 may be physically and electrically spaced apart by the lowermost insulating layer 231a.

In some embodiments, the metal layer 235 may include a material that has an etch selectivity with the redistribution patterns 212 and the through-vias 220. For example, the redistribution patterns 212 and the through-vias 220 include copper (Cu) or an alloy of copper (Cu), The metal layer 235 may include titanium (Ti) or an alloy of titanium (Ti).

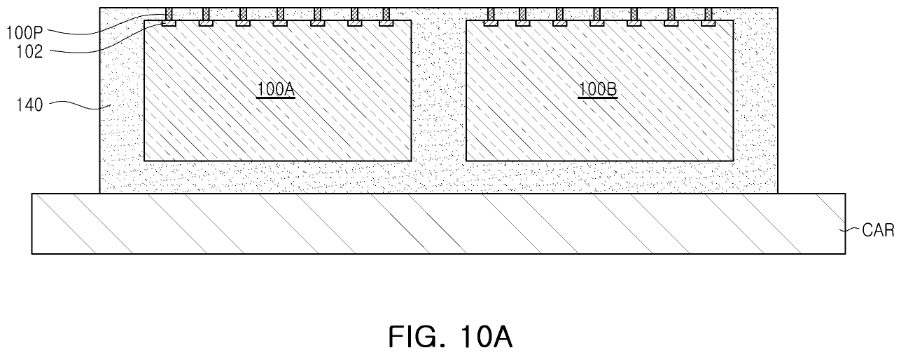

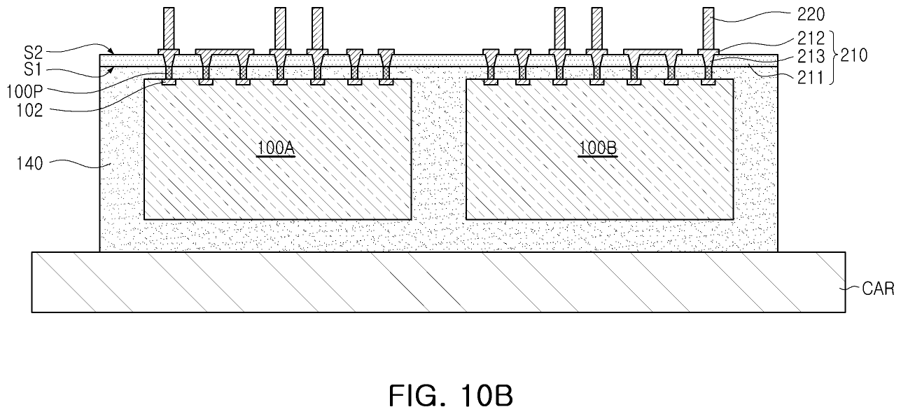

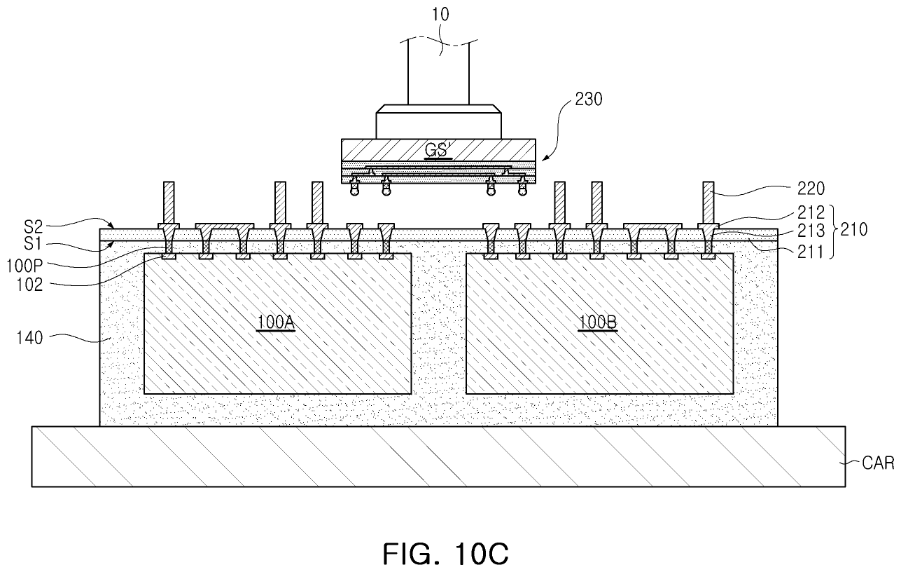

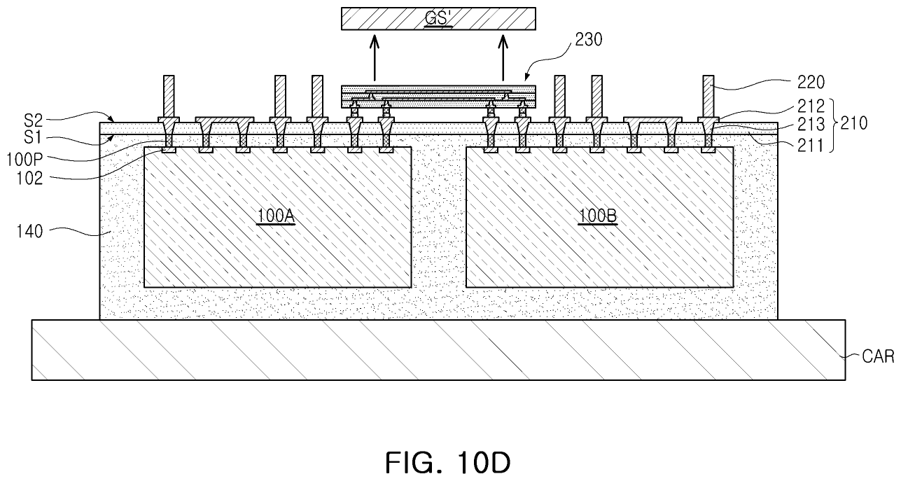

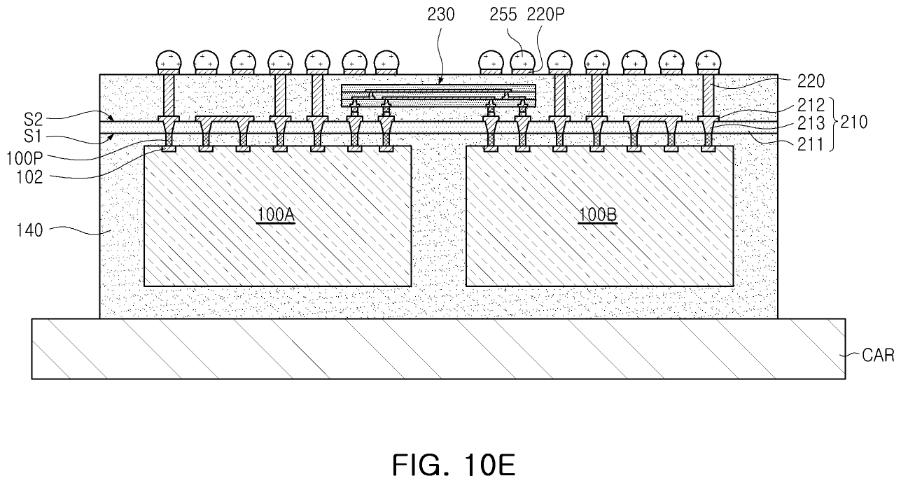

In some embodiments, after interconnect chip 230 is mounted on redistribution structure 210 (see FIG. 10D), only the metal layer 235 may be removed using a wet etching process, without damaging the redistribution patterns 212 and the through-vias 220 having an etch selectivity. In this case, the interconnection chip 230 may be understood as being substantially the same as that described with reference to FIG. 1C and the like.

Additionally, in some embodiments, after the metal layer 235 is removed, a descum process or the like may be additionally performed to form roughness on the surface of the lowermost insulating layer 231a. In this case, the lower surface of the lowermost insulating layer 231a may have a roughness of about 10 Å or more. Similar surface roughness may be formed on a portion of the second surface S2 of the redistribution structure 210, for example, a portion exposed from the interconnection chip 230 and the redistribution patterns 212 (see FIG. 10D).

The metal layer 235 may prevent damage during the pickup and attachment process of the interconnection chip 230 and improve productivity and reliability. The thickness t2 of the metal layer 235 may be equal to or smaller than the thickness t1 of the interconnection patterns 232. For example, the thickness t2 of the metal layer 235 may range from about 0.1 μm to about 2 μm, from 0.1 μm to about 1 μm, from 0.1 μm to about 0.8 μm, or the like. However, the thickness t2 (FIG. 3B) of the metal layer 235 is not limited to the above-mentioned numerical range, and the metal layer 235 may be formed to a thickness that safely handles the interconnection chip 230 made of a flexible material and does not significantly increase the overall thickness of the interconnection chip 230.

In some embodiments, the metal layer 235 may be electrically connected to at least some of the bump structures 255. The metal layer 235 may be connected to the dummy bump pads 220P′. The dummy bump pads 220P′ may include a dummy via portion 220V that penetrates the second mold 240 and contacts the metal layer 235. The metal layer 235 may form a heat dissipation path connected to the dummy bump pads 220P′.

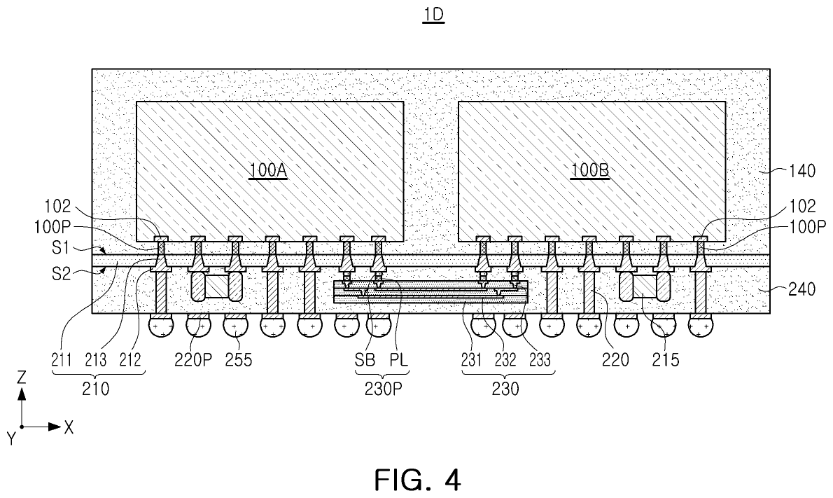

FIG. 4 is a cross-sectional view of a semiconductor package 1D according to an example embodiment.

Reference numerals used herein and labeled in FIGS. 1A-3B are also used herein and labeled in FIG. 4 to designate similar or corresponding components and features of the semiconductor package 1D.

Referring to FIG. 4, the semiconductor package 1D of the example embodiment may have the same or similar features as those described with reference to FIGS. 1A to 3B, except that it further includes a passive component 215 embedded in the second mold 240. The passive component 215 may be mounted on the second surface S2 of the redistribution structure 210. The passive component 215 may be electrically connected to the first chip structure 100A and the second chip structure 100B through the redistribution patterns 212. The passive components 215 may include capacitors such as Multi-Layer Ceramic Capacitor (MLCC) or Low Inductance Chip Capacitor (LICC), inductors such as chip inductors, power inductors, beads, or the like. The number of passive components 215 is not particularly limited and may be provided in larger numbers than illustrated in the drawing.

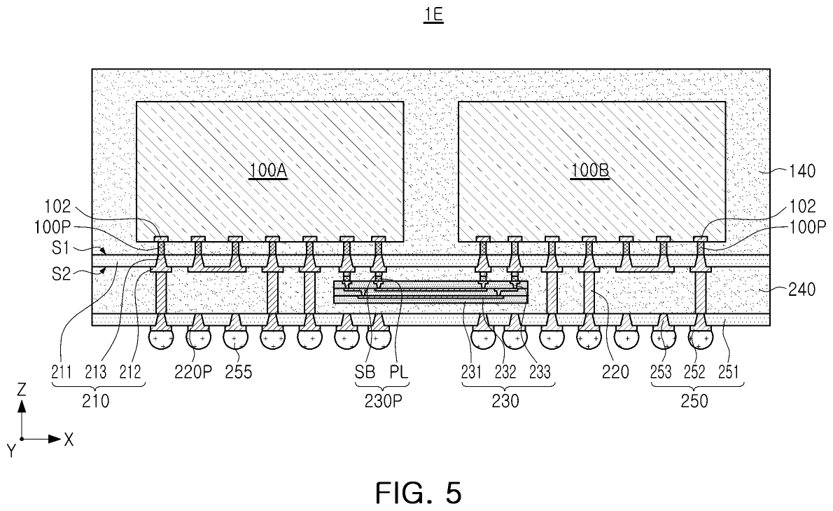

FIG. 5 is a cross-sectional view of a semiconductor package 1E according to further embodiments.

Reference numerals used herein and labeled in FIGS. 1A-4 are also used herein and labeled in FIG. 5 to designate similar or corresponding components and features of the semiconductor package 1E.

Referring to FIG. 5, the semiconductor package 1E of the example embodiment may have the same or similar features as those described with reference to FIGS. 1A to 4, except that it includes a second redistribution structure 250 disposed between the second mold 240 and the bump structures 255. The second redistribution structure 250 may include a second dielectric layer 251, second redistribution patterns 252, and second redistribution vias 253. Since the second dielectric layer 251, the second redistribution patterns 252, and the second redistribution vias 253 have substantially similar characteristics to the above-described first dielectric layer 211, first redistribution patterns 212 and first redistribution vias 213, redundant descriptions are omitted. The second dielectric layer 251 may cover the lower surface of the second mold 240. The second redistribution patterns 252 may include various types of electrically conductive lines extending in the horizontal direction (X, Y) on the lower surface of the second dielectric layer 251. The second redistribution vias 253 may penetrate the second dielectric layer 251 and electrically connect the second redistribution patterns 252 or their pad portions to the through-vias 220. The second redistribution patterns 252 may substantially redistribute the through-vias 220.

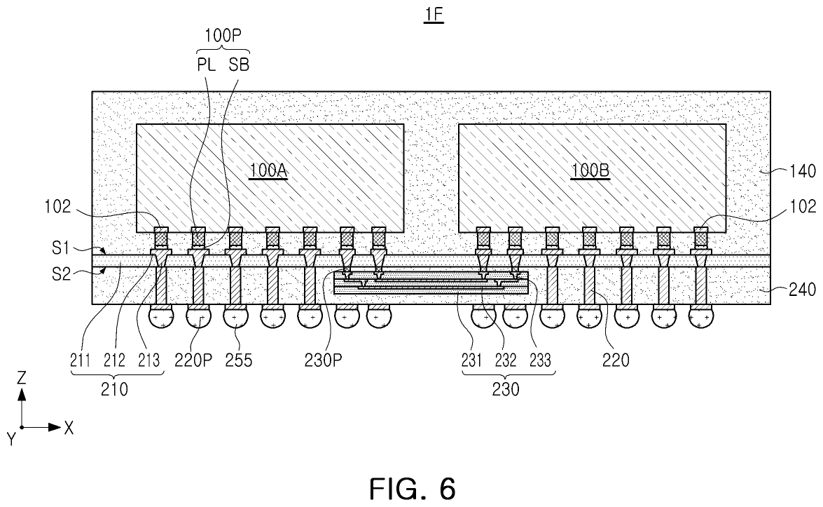

FIG. 6 is a cross-sectional view of a semiconductor package 1F according to further embodiments.

Reference numerals used herein and labeled in FIGS. 1A-5 are also used herein and labeled in FIG. 6 to designate similar or corresponding components and features of the semiconductor package 1F.

Referring to FIG. 6, the semiconductor package 1F of the example embodiment may have the same or similar features as those described with reference to FIGS. 1A to 5, except for the shape of the redistribution structure 210. In an example embodiment, the redistribution structure 210 may include redistribution patterns 212 arranged on the first surface S1, and redistribution vias 213 extend from the redistribution patterns 212 and are electrically connected to the through-vias 220 and the interconnection chip 230. The redistribution vias 213 may have a side surface tapered toward the second surface S2 (i.e., tapers inwardly in a direction from the surface S1 to the surface S2). The first and second chip structures 100A and 100B may be electrically connected to the redistribution patterns 212 or a pad portion thereof through the connection bump 100P. The connection bump 100P may include a solder portion SB on the pillar portion PL. The interconnection chip 230 may be electrically connected to the redistribution vias 213 through interconnection bumps 230P. The interconnection bumps 230P may include metal pillars exposed to the upper surface of the second mold 240.

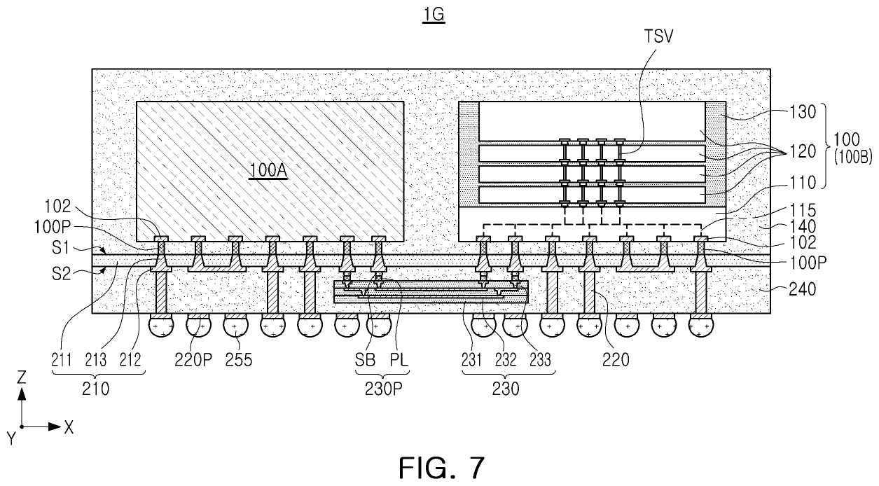

FIG. 7 is a cross-sectional view of a semiconductor package 1G according to further embodiments.

Reference numerals used herein and labeled in FIGS. 1A-6 are also used herein and labeled in FIG. 7 to designate similar or corresponding components and features of the semiconductor package 1G.

Referring to FIG. 7, the semiconductor package 1G of the example embodiment may have the same or similar features as those described with reference to FIGS. 1A to 6, except that the second chip structure 100B is provided as the high-capacity memory device 100. For example, the first chip structure 100A may be a logic chip including an ASIC and the like, and the second chip structure 100B may include a high-capacity memory device 100 including a plurality of memory chips 120, for example, a high bandwidth memory (HBM) device or an electro data processing (EDP) device. For example, the memory device 100 may include a base chip 110, a memory chip 120, and a molding layer 130.

The base chip 110 may be a buffer chip or control chip including a plurality of logic elements and/or memory elements. The base chip 110 may include a buffer circuit or control circuit 115 that transmits signals from the memory chips 120 to the outside and also transmits signals and power from the outside to the memory chips 120.

The memory chips 120 may be memory chips including volatile memory devices such as DRAM and SRAM, or non-volatile memory devices such as PRAM, MRAM, FeRAM, RRAM, and flash memory. The memory chips 120 may be electrically connected to each other through a through electrode (TSV). However, the memory chip 120 disposed at the top does not have a through electrode (TSV) and may have a relatively large thickness.

The molding layer 130 is disposed on the base chip 110 and may seal at least a portion of each of the memory chips 120. The molding layer 130 may be formed to expose the upper surface of the memory chip 120 disposed at the top. The molding layer 130 may be formed using, for example, EMC, but the material of the molding layer 130 is not particularly limited.

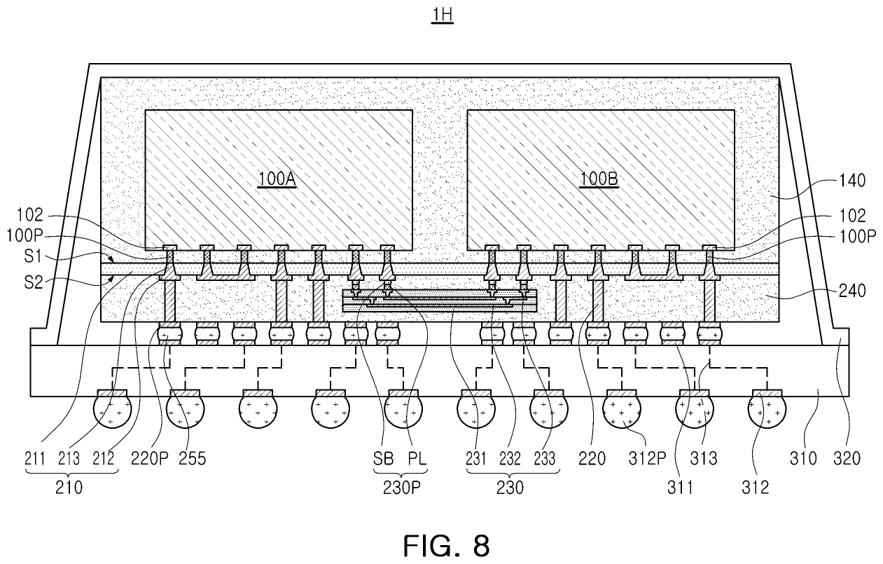

FIG. 8 is a cross-sectional view of a semiconductor package 1H according to further embodiments.

Reference numerals used herein and labeled in FIGS. 1A-7 are also used herein and labeled in FIG. 8 to designate similar or corresponding components and features of the semiconductor package 1H.

Referring to FIG. 8, the semiconductor package 1H of the example embodiment may have the same or similar features as those described with reference to FIGS. 1A to 7, except that the semiconductor package 1H of the example embodiment further includes a base substrate 310 and a heat dissipation structure 320.

The base substrate 310 may be a semiconductor package board such as a printed circuit board (PCB), a ceramic board, or a tape interconnection board. The base substrate 310 may include a lower pad 312, an upper pad 311, and an interconnection circuit 313. The body of the base substrate 310 may contain different materials depending on the type of substrate. For example, when the base substrate 310 is a printed circuit board, the base substrate 310 may be a body copper clad laminate or a form in which an interconnection layer is additionally laminated on one or both side surfaces of a copper clad laminate. An external connection bump 312P connected to the lower pad 312 may be disposed on the lower surface of the base substrate 310. The external connection bump 312P may contain tin (Sn), indium (In), bismuth (Bi), antimony Sb, copper (Cu), silver (Ag), zinc (Zn), lead (Pb) and/or alloys thereof.

The heat dissipation structure 320 is disposed on the upper surface of the base substrate 310 and may be formed to cover upper portions of the plurality of chip structures 100A and 100B. The heat dissipation structure 320 may be attached to the base substrate 310 using an adhesive. The adhesive may be a thermally conductive adhesive tape, thermally conductive grease, or thermally conductive adhesive. In some embodiments, the heat dissipation structure 320 may contact the upper surfaces of the plurality of chip structures 100A and 100B. A layer of thermal interface material may be disposed between the heat dissipation structure 320 and the plurality of chip structures 100A and 100B. The heat dissipation structure 320 may include a material with excellent thermal conductivity, such as metals or metal alloys containing gold (Au), silver (Ag), copper (Cu), iron (Fe), or the like, or a material such as graphite, graphene, or the like. The heat dissipation structure 320 may have a shape different from that illustrated in the drawing. For example, the heat dissipation structure 320 may have a plate shape that covers only the upper surface of the plurality of chip structures 100A and 100B or the upper surface of the first mold 140.

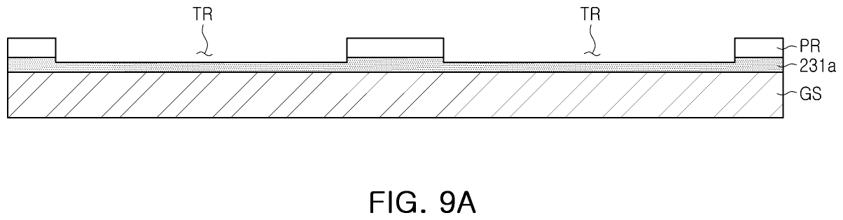

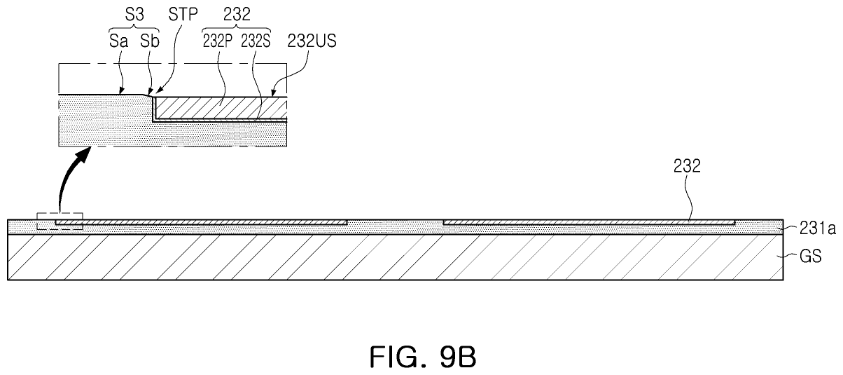

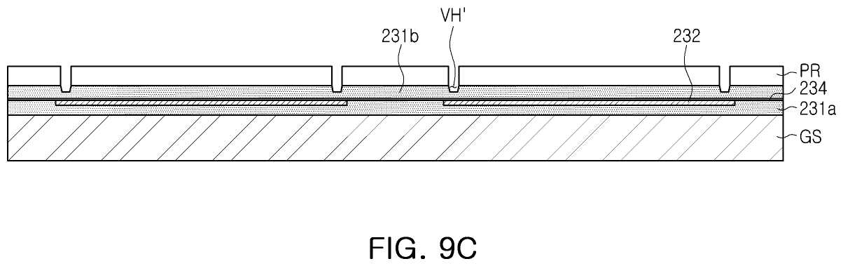

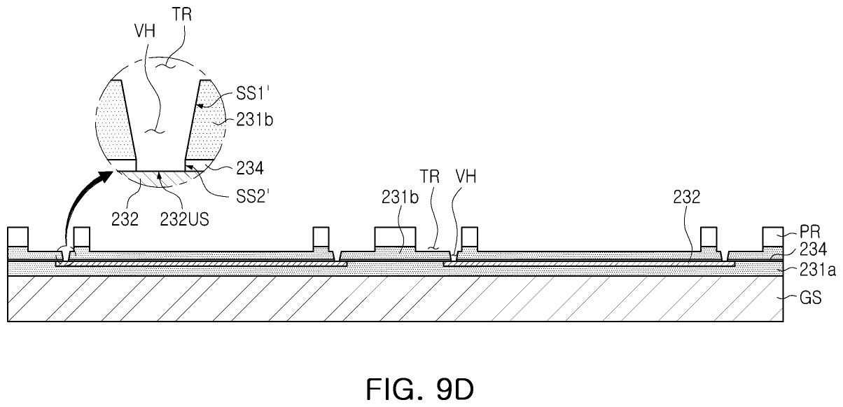

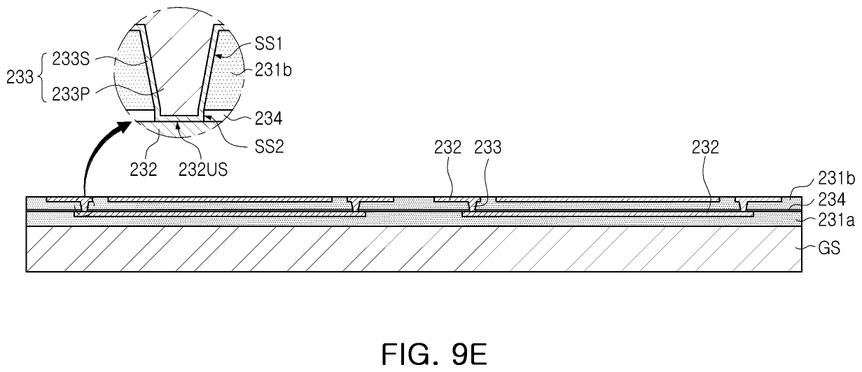

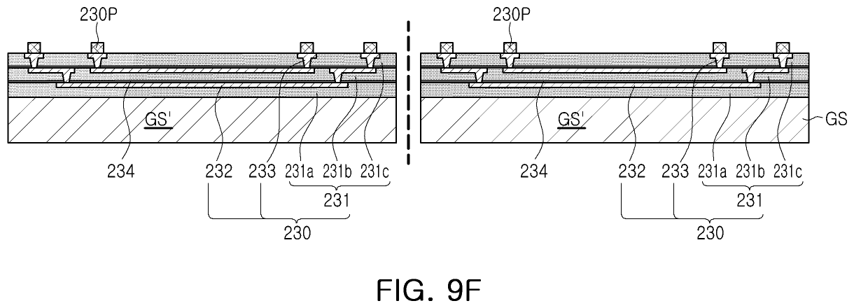

FIGS. 9A to 9F are diagrams illustrating the process of manufacturing the interconnection chip 230 according to an example embodiment. FIGS. 9A to 9F schematically show the process of manufacturing the interconnection chip 230 illustrated in FIGS. 2A and 2B.

Referring to FIG. 9A, a first insulating layer 231a may be formed on the temporary substrate GS. An adhesive layer and/or a metal layer (see ‘235’ in FIG. 3B) may be disposed between the temporary substrate GS and the first insulating layer 231a. The adhesive layer may include an epoxy resin that loses adhesiveness due to ultraviolet light. The first insulating layer 231a may be formed using a photosensitive polymer in a film or paste state. The first insulating layer 231a may include a trench TR formed through an etching process using photoresist PR. For example, a miniaturized trench TR may be formed on the upper surface of the first insulating layer 231a using a dry etching process.

Referring to FIG. 9B, interconnection patterns 232 may be formed in the trench TR of the first insulating layer 231a. The interconnection patterns 232 may include an electrically conductive layer 232P and a seed layer 232S. The seed layer 232S may be formed of a double layer of titanium (Ti) and copper (Cu). The seed layer 232S may be formed using a chemical vapor deposition (CVD) process, a physical vapor deposition (PVD) process, or the like. The conductive layer 232P contains copper (Cu) and may be formed using an electroplating process using the seed layer 232S. A planarization process such as chemical mechanical polishing (CMP) may be applied to the interconnection patterns 232 and the first insulating layer 231a. Through the planarization process, the upper surface S3 of the first insulating layer 231a may include a first region Sa having, defining or forming a step STP with the upper surface 232US of the interconnection pattern 232, and a second region Sb between the first region Sa and the interconnection pattern 232. That is, the upper surface S3 of the first insulating layer 231a includes a first region Sa, and a second region Sb between its first region Sa and the upper surface 232US of the interconnection pattern 232 embedded in the upper surface S3 of the first insulating layer 231a, and the second region Sb defines a step STP between the first region Sa and the upper surface 232US of the interconnection pattern 232 embedded in the upper surface S3 of the first insulating layer 231a. The first region Sa is a flat surface at a higher level than the upper surface 232US of the corresponding interconnection pattern 232. The step STP reduces or transitions the height of the surface S3 from the level or height of the first region Sa to the lower level or height of the upper surface 232US of the interconnection pattern 232 embedded in the upper surface S3 of the first insulating layer 231a. The second region Sb may be a curved surface extending from one end of the first region Sa to one end of the interconnection pattern 232. The upper surface S3 of the first insulating layer 231a may have a roughness of about 10 Å or more by applying a descum process.

Referring to FIG. 9C, a passivation layer 234 and a second insulating layer 231b may be formed. The passivation layer 234 may be formed using a chemical vapor deposition (CVD) process, a physical vapor deposition (PVD) process, or the like. The passivation layer 234 may include silicon oxide, silicon nitride, or the like. The passivation layer 234 may be formed on the entire upper surface of the interconnection patterns 232 and the first insulating layer 231a. The second insulating layer 231b may be formed on the passivation layer 234 using a process similar to that of the first insulating layer 231a. The second insulating layer 231b may include a preliminary via hole VH′ formed through an exposure process using photoresist PR and a wet etching process. The preliminary via hole VH′ may be formed at a depth such that the passivation layer 234 is not exposed. In some embodiments, the preliminary via hole VH′ may be formed to expose the passivation layer 234.

Referring to FIG. 9D, a via hole VH and a trench TR may be formed on the second insulating layer 231b. The via hole VH and trench TR may be formed using an etching process using photoresist PR. First, the second insulating layer 231b may be partially removed using a wet etching process, and a via hole VH exposing the trench TR and the passivation layer 234 may be formed. Next, the passivation layer 234 is partially removed using a dry etching process, and the via hole VH exposing the upper surface 232US of the interconnection pattern 232 may be completed. The via hole VH may include a first side surface SS1′ defined by the second insulating layer 231b and a second side surface SS2′ defined by the passivation layer 234. The first side surface SS1′ and the second side surface SS2′ may have different inclination angles with respect to the upper surface 232US of the interconnection pattern 232.

Referring to FIG. 9E, interconnection patterns 232 and interconnection vias 233 may be formed on the second insulating layer 231b. The interconnection patterns 232 may include an electrically conductive layer 232P and a seed layer 232S covering the side surface and lower surface of the conductive layer 232P. The interconnection vias 233 may include an electrically conductive layer 233P and a seed layer 233S covering the side surface and lower surface of the conductive layer 233P. The conductive layer 232P and the seed layer 232S of the interconnection patterns 232 may be formed integrally with the conductive layer 233P and the seed layer 233S of the interconnection vias 233, but the present inventive concepts are not limited thereto. The interconnection vias 233 may include a first side surface SS1 that passes through the second insulating layer 231b, and a second side surface SS2 that passes through the passivation layer 234. The inclination angle of the second side surface SS2 may be greater than the inclination angle of the first side surface SS1 (see FIG. 3B).

Referring to FIG. 9F, by repeating the above-described process (manufacturing process of FIGS. 9C to 9E), interconnection chips 230 including miniaturized interconnection patterns 232 and a plurality of passivation layers 234 may be formed. The interconnection bumps 230P may be formed on the interconnection patterns 232. The interconnection chips 230 may be individually separated by a sawing process. The interconnection chips 230 formed of a flexible material may be cut together with the temporary substrate GS in preparation for subsequent processing. The interconnection chips 230 may be attached to the unit substrates GS' from which the temporary substrate GS was cut. The unit substrates GS' may be removed after mounting the interconnection chips 230 on the redistribution structure 210 in a subsequent process (see FIG. 10E). In some embodiments, when a metal layer (‘235’ in FIGS. 3A and 3B) is attached to the interconnection chips 230, the interconnection chips 230 may be handled separately from the unit substrates GS′.

FIGS. 10A to 10E are diagrams illustrating a process of manufacturing a semiconductor package according to further embodiments. FIGS. 10A to 10E schematically show the process of manufacturing the semiconductor package 1A of FIG. 1B.

Referring to FIG. 10A, the first chip structure 100A and the second chip structure 100B molded and disposed on the carrier substrate CAR. The first chip structure 100A and the second chip structure 100B may be arranged on the carrier substrate CAR in a face-up shape with each pad 102 facing upward. The first chip structure 100A and the second chip structure 100B may be sealed by the first mold 140 and placed on the carrier substrate CAR. For example, the first chip structure 100A and the second chip structure 100B may be sealed by the first mold 140 while temporarily attached to a tape or the like in a face-down form. The connection bumps 100P may be exposed to the upper surface of the first mold 140.

Referring to FIG. 10B, a redistribution structure 210 and through-vias 220 may be formed. The redistribution structure 210 may include a dielectric layer 211, redistribution patterns 212, and redistribution vias 213. The dielectric layer 211 may be formed using a photosensitive polymer. Redistribution patterns 212 and redistribution vias 213 may be formed on the dielectric layer 211 patterned through a photolithography process. The redistribution patterns 212 and the redistribution vias 213 may be formed using a plating process, an etching process, or the like. Through-vias 220 may be formed on at least some of the redistribution patterns 212 or the pad portion thereof. The redistribution patterns 212, the redistribution vias 213, and the through-vias 220 may include copper (Cu) or alloys thereof, but are not limited thereto.

Referring to FIG. 10C, the interconnection chip 230 may be mounted on the redistribution structure 210. Interconnect chip 230 may be handled using a pick-up tool 10. The pick-up tool 10 may handle the interconnection chip 230 by adsorbing the unit substrate GS' attached to the interconnection chip 230. When the metal layer 235 of FIG. 3B is attached to the interconnection chip 230, the unit substrate GS' may be omitted.

Referring to FIG. 10D, after the interconnection chip 230 is mounted, the unit substrate GS' may be removed. The unit substrate GS' may be separated by irradiating a laser, ultraviolet light, or the like to the adhesive layer between the unit substrate GS' and the interconnection chip 230. When the metal layer 235 of FIG. 3B is attached to the interconnection chip 230, the interconnection chip 230 may be handled without the unit substrate GS′, and the removal process of the unit substrate GS' may be omitted.

Referring to FIG. 10E, the second mold 240 and bump structures 255 may be formed. The second mold 240 may be formed to surround the side surface and upper surfaces of the interconnection chip 230 and the side surfaces of the through-vias 220. Through the planarization process, the upper surfaces of the through-vias 220 may be exposed onto the second mold 240. When the metal layer 235 of FIG. 3B is attached to the interconnection chip 230, the planarization process may proceed until the metal layer 235 is exposed. Thereafter, bump pads 220P and bump structures 255 may be formed on the second mold 240. According to example embodiments, a semiconductor package with improved productivity and reliability may be manufactured by safely handling the thinned interconnection chip 230.

As set forth above, according to example embodiments, a semiconductor package with improved productivity and reliability may be provided by introducing an interconnection chip including a flexible material.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a redistribution structure having a first surface and a second surface opposing each other, and including redistribution patterns;
a first chip structure and a second chip structure disposed on the first surface of the redistribution structure and electrically connected to the redistribution patterns;
a first mold covering at least a portion of each of the first and second chip structures;
an interconnection chip disposed on the second surface of the redistribution structure, and including:
interconnection patterns electrically connected to the redistribution patterns; and
a plurality of insulating layers each having a third surface;
wherein each of the third surfaces includes a respective one of the interconnection patterns embedded therein;
through-vias disposed around the interconnection chip and electrically connected to the redistribution patterns;
a second mold covering at least a portion of each of the through-vias and the interconnection chip; and
bump structures disposed below the second mold and electrically connected to the through-vias;
wherein each third surface includes:
a first region; and
a second region between the first region and an upper surface of the respective interconnection pattern embedded in said third surface; and
wherein the second region defines a step between the first region and the upper surface of the respective interconnection pattern embedded in said third surface.

2. The semiconductor package of claim 1, wherein each of the second regions is a curved surface extending from one end of the corresponding first region to one end of the respective interconnection pattern.

3. The semiconductor package of claim 1, wherein each of the first regions is on a higher level than the upper surface of the respective interconnection pattern.

4. The semiconductor package of claim 1, wherein:
the interconnection chip further includes a plurality of passivation layers between the upper surfaces of the interconnection patterns and the plurality of insulating layers; and
the plurality of passivation layers include a material different from a material of the plurality of insulating layers.

5. The semiconductor package of claim 4, wherein the plurality of passivation layers include at least one of silicon oxide, silicon nitride, and silicon oxynitride.

6. The semiconductor package of claim 4, wherein:
the interconnection chip further includes interconnection vias extending from lower surfaces of at least some of the interconnection patterns to the upper surfaces of the interconnection patterns corresponding thereto; and
the interconnection vias include a first side surface passing through the plurality of insulating layers and a second side surface passing through the plurality of passivation layers.

7. The semiconductor package of claim 6, wherein:
the first side surface of each of the interconnection vias has a first inclination angle with respect to the upper surfaces of the interconnection patterns corresponding thereto; and
the second side surface of each of the interconnection vias has a second inclination angle greater than the first inclination angle, with respect to the upper surfaces of the interconnection patterns corresponding thereto.

8. The semiconductor package of claim 1, wherein:
the plurality of insulating layers include a photosensitive polymer; and
the first and second molds include a non-photosensitive polymer.

9. The semiconductor package of claim 8, wherein:
the redistribution structure further includes a dielectric layer on which the redistribution patterns are disposed; and
the dielectric layer includes a photosensitive polymer.

10. The semiconductor package of claim 8, wherein the second mold is in direct contact with a lower surface of a lowermost insulating layer among the plurality of insulating layers.

11. The semiconductor package of claim 1, wherein the plurality of insulating layers have substantially the same thickness.

12. The semiconductor package of claim 1, wherein the interconnection patterns include an electrically conductive layer and a seed layer covering a side surface and a lower surface of the electrically conductive layer.

13. The semiconductor package of claim 12, wherein:
the electrically conductive layer includes any one of copper (Cu), nickel (Ni), titanium (Ti), aluminum (Al), gold (Au), and silver (Ag), or alloys thereof; and
the seed layer includes titanium (Ti), tantalum (Ta), or alloys thereof.

14. The semiconductor package of claim 1, wherein:
the redistribution structure further includes a dielectric layer defining the first and second surfaces, and redistribution vias penetrating the dielectric layer and electrically connecting the redistribution patterns disposed on the second surface to the first and second chip structures; and
the redistribution vias have side surfaces tapered toward the first surface.

15. The semiconductor package of claim 1, wherein the first and second chip structures are electrically connected to each other through the interconnection chip.

16. A semiconductor package comprising:
a first redistribution structure having a first surface and a second surface opposing each other, and including first redistribution patterns;
a first chip structure and a second chip structure disposed on the first surface of the first redistribution structure and electrically connected to the first redistribution patterns;
a first mold covering at least a portion of each of the first and second chip structures;
an interconnection chip disposed on the second surface of the first redistribution structure, and including:
a chip body;
interconnection patterns embedded within the chip body and electrically connected to the first redistribution patterns; and
a metal layer disposed below the chip body;
through-vias disposed around the interconnection chip and electrically connected to the first redistribution patterns;
a second mold covering the interconnection chip and at least portions of the through-vias; and
bump structures disposed below the second mold and electrically connected to the through-vias;
wherein the chip body includes a flexible material; and
wherein the metal layer is electrically insulated from the interconnection patterns.

17. The semiconductor package of claim 16, wherein a thickness of the metal layer is equal to or smaller than a thickness of the interconnection patterns.

18. The semiconductor package of claim 16, wherein the metal layer is electrically connected to at least some of the bump structures.

19. The semiconductor package of claim 16, further comprising a second redistribution structure disposed between the second mold and the bump structures and including second redistribution patterns electrically connecting the through-vias and the bump structures.

20. A semiconductor package comprising:
a redistribution structure having a first surface and a second surface opposing each other, and including redistribution patterns;
a first chip structure and a second chip structure disposed on the first surface of the redistribution structure and electrically connected to the redistribution patterns;
a first mold covering at least a portion of each of the first and second chip structures;
an interconnection chip disposed on the second surface of the redistribution structure, and including:
a chip body;
interconnection patterns embedded in the chip body and electrically connected to the redistribution patterns; and
a plurality of passivation layers disposed between the chip body and the redistribution patterns;
through-vias disposed around the interconnection chip and electrically connected to the redistribution patterns;
a second mold covering a side surface and a lower surface of the interconnection chip and respective side surfaces of the through-vias; and
bump structures disposed below the second mold and electrically connected to the through-vias;
wherein the chip body contains an organic compound; and
wherein the plurality of passivation layers contain an inorganic compound.
